(19) United States
(12) Patent Application Publication
(10) Pub. No.: US 2015/0288387 A1
(43) Pub. Date: Oct. 8, 2015

(54) METHODS AND APPARATUS FOR DECODING

(71) Applicant: NOKIA CORPORATION, Espoo (FI)

(72) Inventors: Xianjun Jiao, Beijing (CN); Berg Heikki, Seinajoki (FI); Canfeng Chen, Beijing (CN)

(21) Appl. No.: 14/437,575

(22) PCT Filed: Dec. 14, 2012
(86) PCT No.: PCT/CN2012/086675

§ 371 Date: Apr. 22, 2015

(51) Int. Cl. H03M 13/37; G06F 11/10

(52) U.S. Cl. CPC H03M 13/3746; G06F 11/1076

(57) ABSTRACT

Systems and techniques for decoding of data are described. A plurality of sub-decoders are defined, with the number of sub-decoders being limited only by a number of bits of a codeblock to be processed. A number of iterations is defined for the sub-decoders based on a desired maximum block error rate. Sub-decoders may run asynchronously.

### TECHNICAL FIELD

The present invention relates generally to decoding. More particularly, the invention relates to improved parallel processing for decoding of probabilistic data.

### BACKGROUND

Modern wireless communication systems have been designed to transfer large amounts of data between transmitter and receiver. Communication system operators are constantly seeking mechanisms for robust transmission of data. Probabilistic decoding of data is particularly useful for data to be transmitted in a noisy environment, and a number of probabilistic decoding techniques, such as turbo codes, low density parity check, and ZigZag code have been developed. For example, turbo codes have been used in many wireless communication standards as a Forward Error Correction (FEC) scheme, for example, WCDMA, CDMA2000, LTE, LTE-A, WiMAX, and the like and increasing attention has been given to decoding turbo code at higher throughput and lower cost.

A turbo decoder performs decoding of a block of channel bits into a block of information bits. If a single decoder is used to decode the block of channel bits, and it is assumed that the decoder can process N bits per second, the decoding time of one block of M bits would be M/N.

A general method to improve throughput is splitting a block of channel bits into P sub-blocks, and using P sub-decoders to decode according sub-blocks of input block concurrently. Thus, the overall time of decoding one block can be divided by a factor P, and throughput can thus be increased by the factor of P (assuming that every sub-decoder maintains the same processing capability of processing N bits per second).

In many prior-art cases, a turbo decoder is implemented by an application-specific integrated circuit (ASIC) or a field programmable gate array (FPGA.) The configuration (number of sub-decoders, memory banks, etc.) of ASICs or FPGAs may be customized according to requirements related to processing delay or throughput. After the design is completed or an ASIC is manufactured, however, the configuration and performance of a turbo decoder is difficult to change.

### SUMMARY

In one embodiment of the invention, an apparatus comprises at least one processor and memory storing computer program code. The memory storing the computer program code is configured to, with the at least one processor, cause the apparatus to at least define a plurality of sub-decoders for parallel decoding of at least one codeblock of data, wherein the maximum number of sub-decoders defined is limited by a bit length of the at least one codeblock, divide the at least one codeblock of data into a plurality of sub-blocks, wherein each of the sub-blocks is allocated to one of the sub-decoders, define a number of iterations to be performed by each sub-decoder, wherein the number of iterations to be performed is based on a number of iterations needed to achieve a targeted block error rate, and perform simultaneous processing of the sub-blocks by the sub-decoders over the defined number of iterations.

In another embodiment of the invention, a method comprises defining a plurality of sub-decoders for parallel decoding of at least one codeblock of data, wherein the maximum number of sub-decoders defined is limited by a bit length of the at least one codeblock, dividing the at least one codeblock of data into a plurality of sub-blocks, wherein each of the sub-blocks is allocated to one of the sub-decoders, defining a number of iterations to be performed by each sub-decoder, wherein the number of iterations to be performed is based on a number of iterations needed to achieve a targeted block error rate, and performing simultaneous processing of the sub-blocks by the sub-decoders over the defined number of iterations.

In another embodiment of the invention, a computer readable medium stores a program of instructions, execution of which by a processor configures an apparatus to at least define a plurality of sub-decoders for parallel decoding of at least one codeblock of data, wherein the maximum number of sub-decoders defined is limited by a bit length of the at least one codeblock, divide the at least one codeblock of data into a plurality of sub-blocks, wherein each of the sub-blocks is allocated to one of the sub-decoders, define a number of iterations to be performed by each sub-decoder, wherein the number of iterations to be performed is based on a number of iterations needed to achieve a targeted block error rate, and perform simultaneous processing of the sub-blocks by the sub-decoders over the defined number of iterations.

In another embodiment of the invention, a method comprises dividing at least one block of data to be processed into a plurality of sub-blocks for parallel processing and processing the sub-blocks simultaneously in parallel processors over a plurality of iterations, wherein the number of iterations is chosen based on a need to achieve a targeted error rate.

In another embodiment of the invention, an apparatus comprises at least one processor and memory storing computer program code. The memory storing the computer program code is configured to, with the at least one processor, cause the apparatus to at least divide at least one block of data to be processed into a plurality of sub-blocks for parallel processing and process the sub-blocks simultaneously in parallel processors over a plurality of iterations, wherein the number of iterations is chosen based on a need to achieve a targeted error rate.

### BRIEF DESCRIPTION OF THE DRAWINGS

FIG. 1 illustrates an encoder that may generate data for decoding using one or more embodiments of the present invention;

FIGS. 2 and 3 illustrate a structure for turbo decoding that may be implemented using embodiments of the present invention;

FIG. 4 illustrates a graph plotting iteration requirements against number of sub-decoders for an embodiment of the present invention;

FIG. 5 illustrates a graph plotting ideal speedup ratio against number of sub-decoders for an embodiment of the present invention;

FIG. 6 illustrates a prior-art memory arrangement;

FIG. 7 illustrates a memory arrangement according to an embodiment of the present invention;

FIG. 8 illustrates using two simultaneous threads to perform forward and reverse transversal for one sub-decoder according to an embodiment of the present invention;

FIG. 9 illustrates a two simultaneous thread configuration according to an embodiment of the present invention;

FIG. 10 illustrates a representation of thread grouping and running with step differences according to an embodiment of the present invention;

FIG. 11 illustrates a graphical representation of data exchange between asynchronous threads according to an embodiment of the present invention;

FIGS. 12 and 13 illustrate graphs plotting tolerance of max diff against probability of asynchronicity under different conditions according to embodiments of the present invention; and

FIG. 14 illustrates elements that may be used in carrying out embodiments of the present invention.

### DETAILED DESCRIPTION

One or more embodiments of the present invention recognize that, particularly in the face of rapid changes in performance or standards requirements, customized hardware design suffers from shortcomings such as long development periods and inflexibility in performance, resource demands, or power demands. Probabilistic decoding frequently involves substantial iterative processing of data and may involve processing of large volumes of data, and hardware implementation of such mechanisms may be complex and difficult to change.

One mechanism for probabilistic iterative processing is turbo decoding, and, in the area of software defined radio (SDR) (Software Defined Radio), more and more attention has been paid to a software defined turbo decoder. A software decoder can be adapted to many situations easily—for example, different UE category, different standards, etc. However, many software decoders, such as central processing unit (CPU) based, digital signal processor (DSP) based, etc., have poor throughput performance.

Embodiments of the invention further recognize that GPGPU is an emerging computation platform which may have much higher peak FLOPS (Floating Point Operations Per Second) than a central processing unit (CPU) or digital signal processor (DSP), or which alternatively may present a much lower cost compared to a CPU or DSP which provides similar peak FLOPs. Unlike a CPU or DSP having a number of complicated cores with high clock rates, GPGPU has many simple cores with lower clock rate—for example, hundreds or thousands of cores—the use of massive data or task parallelism can take advantage of the capabilities provided by such large numbers of cores. GPGPU program are often developed using CUDA (which, however, can be used only for Nvidia GPU) or OpenCL (Open Computing Language, which is a royalty-free cross-platform parallel programming standard). Embodiments of the present invention recognize that any number of mechanisms for probabilistic iterative decoding can take advantage of such parallelism.

The following discussion presents turbo decoding as an example of a probabilistic iterative mechanism that can be adapted to the use of massive parallel processing, but the present invention is not limited to turbo decoding and it will be recognized that the principles of the invention may easily be adapted to any of a number of other mechanisms for probabilistic iterative decoding existing now or developed in the future.

A number of definitions of terms used in the present application are presented here:
Decoder—a decoder (for example, a turbo decoder) to decode one codeblock (or bits block, or block of bits) into one block of information bits.
Sub-decoder—equivalent to “thread”. One decoder can be implemented by many parallel sub-decoders (or threads).
Thread—equivalent to sub-decoder.
Group—also called workgroup or ‘thread group’. A group of threads, with threads in one group capable of being synchronized.
Processor—or multi-core processor. A processor may employ multiple cores and can execute multiple independent groups of threads. (one group of threads cannot run across multiple processors)
Core—processing element in a processor. One processor may have multiple cores.

The following discussion presents an overview of turbo encoding and decoding, and then further discussion describes various techniques for parallel processing and for increased efficiency and flexibility in such parallel processing.

A turbo encoder receives M bits from an information source, and generates three data sets: the first may be referred to as info0, which is the same as the original information bits block; the second may be referred to as parity0, which is M parity bits generated by component encoder1; the third may be referred to as parity1, which is M parity bits generated by component encoder2, where the input information block info1 is an interleaved version of info0. Then the three types of data are multiplexed into a transmission channel.

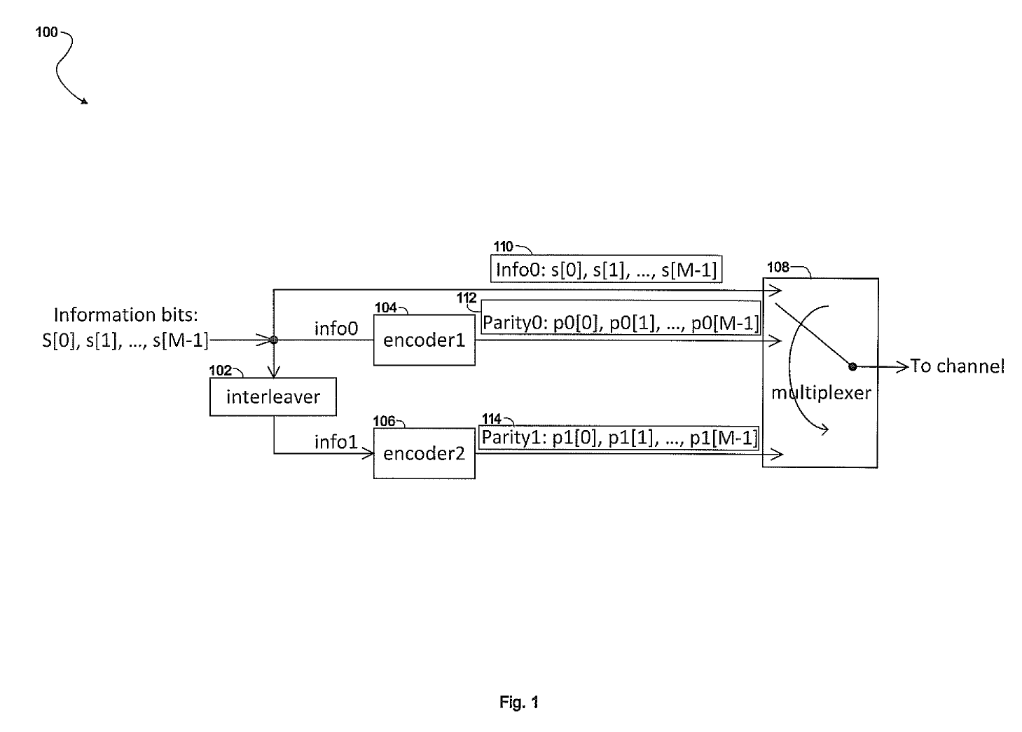

FIG. 1 illustrates a turbo encoder 100 according to an embodiment of the present invention. The turbo encoder 100 comprises an interleaver 102, and first and second encoders 104 and 106, as well as a multiplexer 108. Information bits are fed to the encoder and separated into a first data set 110, second data set 112, generated by the first encoder 104, and third data set 114, generated by the second encoder 106. The first, second, and third data sets 110, 112, and 114 are fed to the multiplexer 108 which creates a multiplexed stream that is placed into a communication channel.

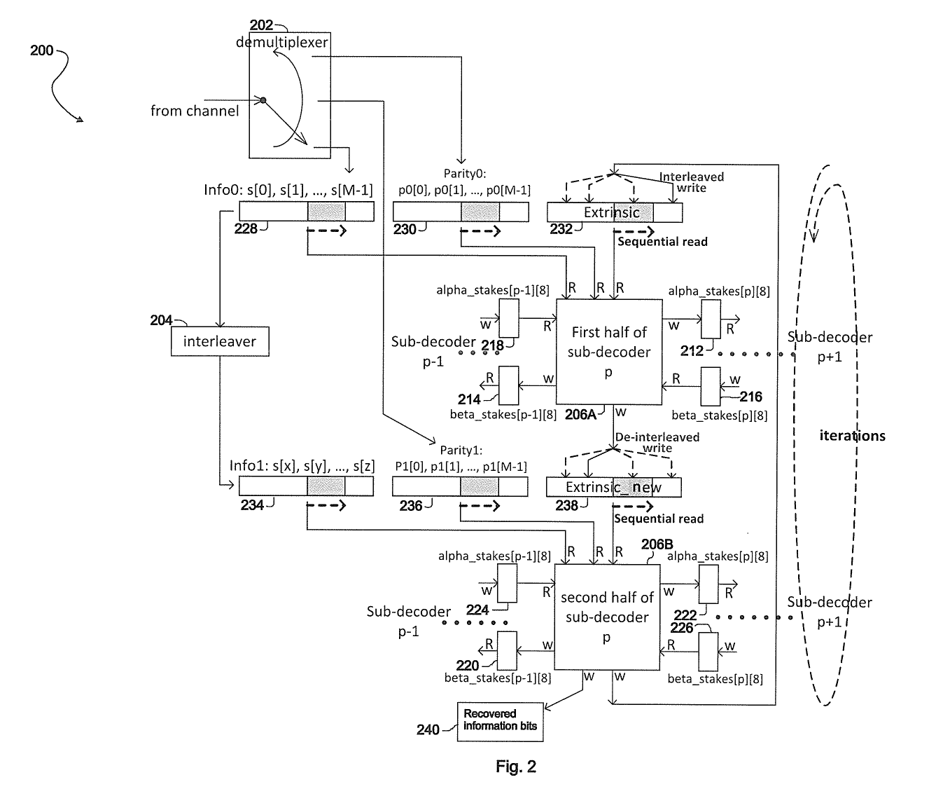

FIG. 2 illustrates a turbo decoder 200 according to an embodiment of the present invention. The decoder 200 comprises a demultiplexer 202, which receives channel bits from the channel, as well as an interleaver 204. The present exemplary turbo decoder 200 comprises a plurality of sub-decoders, of which a representative example sub-decoder p is illustrated here, implemented as first half 206A and second half 206B. The first half 206A processes write buffer objects 212 and 214, and read buffer objects 216 and 218. The second half 206B processes write buffer objects 220 and 222, and read buffer objects 224 and 226. A plurality of additional sub-decoders p+1 and so on are also implemented simultaneously, with all sub-decoders performing multiple iterations simultaneously.

Iterations of sub-decoders may be executed successively as: first half, second half, first half, second half, and so on. In the process of iteration, write buffer objects are updated by program write operation and read buffer objects are read by program read operations. In the present example, the first half and second half of a sub-decoder do not correspond to two separate hardware blocks, but correspond instead to two segments of program code that may be run in the same hardware (or processor) in turn. The first and second halves may be run on the same hardware, so that there need be no issue of hardware relating to one half being idle when the other half is running.

Various preparations are undertaken before the sub-decoders begin their concurrent operation. As an inverse process of a multiplexing operation, such as the multiplexing operation 108, in a turbo encoder, channel data is de-multiplexed into three parts: info0, parity0, parity1. Moreover, info0 is interleaved to create info1. Meanwhile, alpha stake[0] buffer (both first half and second half) and beta_stakes[P] buffer (both first half and second half) should be initialized according to known initial trellis states and ending trellis states of two component encoders. If an encoder has 8 states, the second dimension size of stakes is 8). Leaving out alpha_stake[0] buffer and beta_stakes[P] buffer, other stakes buffers should be initialized with zeros, which means all stakes have equal probability (notice that there are total P+1 alpha_stakes buffers and P+1 beta_stakes buffers for each half of the sub-decoder). An extrinsic buffer should be initialized with zeros, which means there is no knowledge of information bits before the beginning of decoding process. FIG. 2 illustrates buffer objects 228, 230, and 232, which store info0, parity0, and extrinsic data, respectively, and are used by the first half sub-decoder 206A. FIG. 2 further illustrates buffer objects 234, 236, and 238, which store info1, parity1, and extrinsic new data, respectively, and are used by the second half sub-decoder 206B. During operation, the extrinsic data is written by the second half sub-decoder 206B and read by the first half sub-decoder 206A and the extrinsic new data is written by the first half sub-decoder 206A and read by the second half sub-decoder 206B, but as noted above, the extrinsic buffers are populated with initial data before processing begins.

At the end of the preparation, available information is read-only info0 and parity0 for all first half sub-decoders; read-only info1 and parity1 for all second half sub-decoders; and stakes. Also, the extrinsic buffer is initialized.

After the preparation, the iteration of all sub-decoders begins. As an example, the sub-decoder p is discussed here in detail. At first, the first half of the sub-decoder reads alpha_stakes[p−1] and beta_stakes[p] to initialize inner forward initial states and reverse initial states. Then the corresponding portions of info0, parity0, and extrinsic buffer are read, along with performing M/P stages forward transversal calculations. For forward transversal calculations, the corresponding portion and read sequence is from index [p*M/P], [(p*M/P)+1], . . . , to [(p*M/P)+(M/P)−1]. Reverse transversal calculations follow, and the corresponding read sequence of info0, parity0 and extrinsic runs from index [(p*M/P)+(M/P)−1], [(p*M/P)+(M/P)−2], . . . , to [p*M/P]. Meanwhile in the process of reverse transversal, extrinsic values are calculated and stored into extrinsic_new buffer in de-interleaved order. At the end of forward transversal, inner last trellis states are stored to alpha_stakes[p] buffer. At the end of reverse transversal, inner last trellis states are stored to beta_stakes[p−1] buffer.

Essentially, the second half of the sub-decoder performs the same operation as the first half of the sub-decoder, except that second half sub-decoder reads and writes different buffers. Another difference is that the second half sub-decoder writes the extrinsic buffer at interleaved order, while the first half sub-decoder writes extrinsic_new buffer in de-interleaved order.

The number of iterations chosen for the first half and second half sub-decoders takes into account a need to balance BLER performance and processing time. As the number of iterations increases, BLER performance improves. Generally speaking, the use of 6 iterations may be seen as an appropriate tradeoff between BLER performance and processing time, when M/P is larger than 48.

Each sub-decoder uses stake memory data, which actually comes from results of the adjacent sub-decoder in previous iteration. The stake can be viewed as “old” data from a previous iteration. Processing produces recovered information bits 240, written by the second half sub-decoder 206B.

FIG. 3 illustrates a decoder 300 according to another embodiment of the present invention. The decoder 300 is similar to the decoder 200 and includes similar elements to those of the decoder 200. That is, the decoder 300 comprises a demultiplexer 302, interleaver 304, first half sub-decoder 306A and second half sub-decoder 306B. The decoder 300 further comprises write buffer objects 312 and 314, and read buffer objects 316 and 318, as well as write buffer objects 320 and 322 and read buffer objects 324 and 326, and additionally includes buffer objects 328, 330, 332, 334, 336, and 338, with the second half sub-decoder writing recovered information bits 340. The decoder 300 illustrated here is implemented such that the first half employs sequential read and sequential write, while the second half employs interleaved read and interleaved write.

Embodiments of the present invention bring sufficient advantages by introducing modifications to turbo decoders such as those described above.

1. Massive parallelism. Significant difference between GPGPU and CPU (or DSP) is that GPGPU supports much higher parallelism through the use of many more cores, and has appropriate memory systems, thread schedulers, and synchronization mechanisms adapted to this massive parallel architecture.

However, traditional turbo decoders involve limited parallelism—that is, a limited number of sub-decoders—because BLER (Block Error Rate) performance would suffer from greater and greater edge effect caused by segmenting one codeblock to multiple sub-blocks each processed by a sub-decoder. Generally, if the number of sub-decoders is increased so that the length of the channel bits block has to be split into sub-blocks which contain fewer than 48 information bits, there will be notable BLER performance loss. Therefore, embodiments of the invention address ways to define sufficient sub-decoders to fulfill GPGPU's parallel resources in order to achieve higher throughput while maintaining BLER performance by distributing sub-decoders in a multi-processor configuration and running the sub-decoders asynchronously over more iterations.

2. Optimized data arrangement in memory adapted to massive parallel accessing. Because memory stores substantial data to be processed and intermediate results in memory need to be accessed by many sub-decoders, memory accessing performance an important condition affecting throughput performance of turbo decoder. Various approaches according to one or more embodiments of the invention arrange data in memory in a manner which allow massive sub-decoders (or threads) more efficient access to memory by arranging data belonging to an adjacent thread in an adjacent address.

3. Accessing one buffer object by two mapped sub-buffer objects (first half and second half) to accommodate concurrent forward and reverse transversal accessing of one buffer from one thread. Concurrent forward and reverse transversal means that forward transversal accesses the memory region from lowest address to highest address; meanwhile reverse transversal accesses the same memory region from highest address to lowest address. More importantly, the two threads will not access the same address at the same time. If only one buffer is used such access, parallel memory access is difficult to achieve, because the addresses of forward and reverse transversal are usually calculated at runtime. If this parallelism can be discovered at the compiling phase, it would increase efficiency and provide for a more efficient program. Embodiments of the invention therefore provide mechanisms for notification of a compiler of GPGPU programs to allow such parallel memory access. In one or more embodiments, for example, such parallel memory access may be allowed by explicitly defining sub-buffers in source code.

4. Loose synchronization. In a traditional turbo decoder, all sub-decoders (or threads) must be synchronized strictly. However, keeping massive parallel threads strictly synchronized involves high overhead and thus decreases performance. Furthermore, real hardware is unable to support arbitrary number of synchronized threads. For example, most GPGPU (or OpenCL) platform support a maximum 1024 threads in one group, which means that threads in the same group have ability to synchronize with each other, while there is no mechanism to achieve accurate synchronization between different groups.

Generally, a GPGPU platform can support many groups of concurrent threads, and one or more embodiments of the invention provide mechanisms allowing use of many parallel groups in GPGPU—for example, by running sub-decoders and exchanging data between sub-decoders asynchronously.

5. In a complicated multi-task multi-processor software system environment, different processors may have different work loads. When a turbo decoder task is undertaken by the system, advantages may be gained from dividing decoding tasks between different processors according to their current or near future workloads to avoid workload unbalance. In one or more embodiments, the invention provides for a non-uniform codeblock segmenting scheme so as to implement different sub-decoders with different computation loads (or different length of bits to process). Thus it can be adapted to different processors with different work loads or with different capabilities, and achieve a workload balance at the system level.

In one or more embodiments, the invention provides for an ultra-high parallel turbo decoder to achieve high occupancy of GPGPU parallel hardware resources, and accomplishes such high occupancy while maintaining negligible BLER performance loss. Ultra-high parallelism provides for a maximum of M sub-decoders to decode a block of M information bits, and uses techniques described below to overcome edge effect. Such techniques reduce or eliminate the need to limit the number of sub-decoders to a lesser number based, for example, on a need to keep a ratio of M/P (where P is the number of sub-decoders) below a specified number such as 96 or 48.

Embodiments of the invention increase the number of iterations of every sub-decoder in order to reduce edge effect, where the number of iterations is the number of times a sub-decoder repeats execution. Although increasing iterations would linearly increase the execution time of sub-decoders, but increasing the number of sub-decoders increases parallelism, and with this greater parallelism, the overall overall decoding time is still reduced. This is true because if the number of sub-decoders is increased by a factor of Q, the number of bits to be processed by every sub-decoder would be decreased by the same factor of Q. If the number of iterations does not change, then, the execution time of every sub-decoder is reduced by a factor of Q. Though the number of iterations must be increased to overcome edge effect, the increase in the number of iterations is less than Q, so that overall decoding time can be reduced.

Taking LTE turbo codes with 6144 bits length as an example, the following table gives different number of iterations used for a different number P of sub-decoders with a target BLER of less than 0.05.

| | P | | | | | | | | | | | | | | |
|---|---|---|---|---|---|---|---|---|---|---|---|---|---|---|---|
| | 8 | 16 | 64 | 96 | 128 | 192 | 256 | 384 | 512 | 768 | 1024 | 1536 | 2048 | 3072 | 6144 |
| iterations | 6 | 6 | 6 | 6 | 7 | 7 | 8 | 9 | 10 | 12 | 15 | 20 | 26 | 35 | 65 |

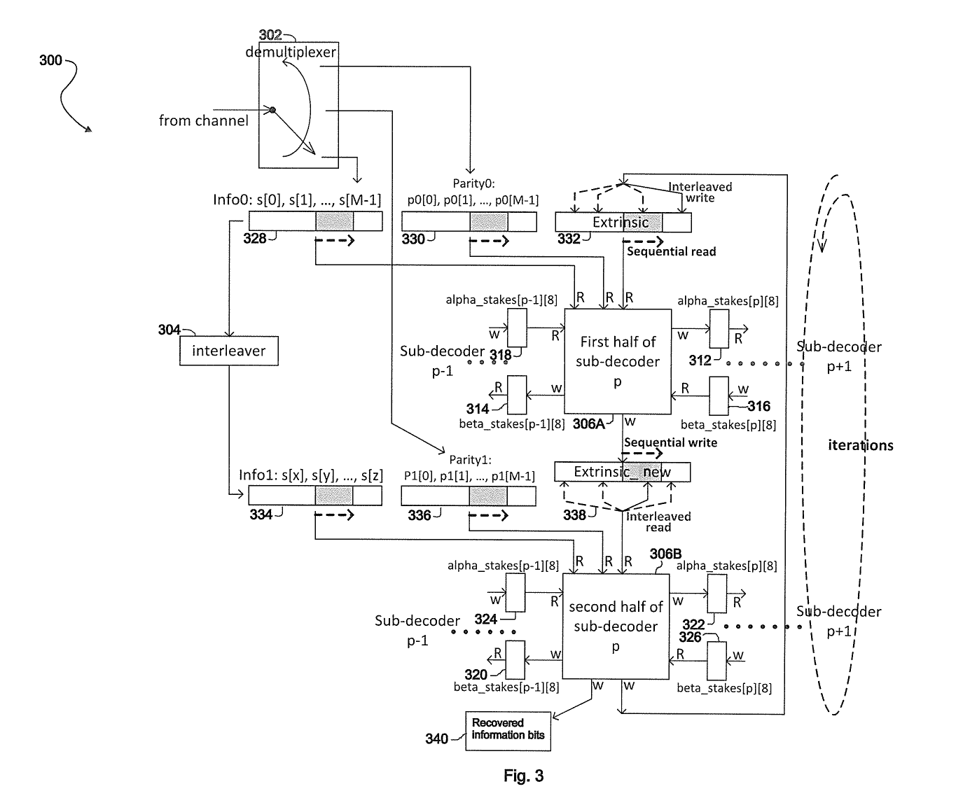

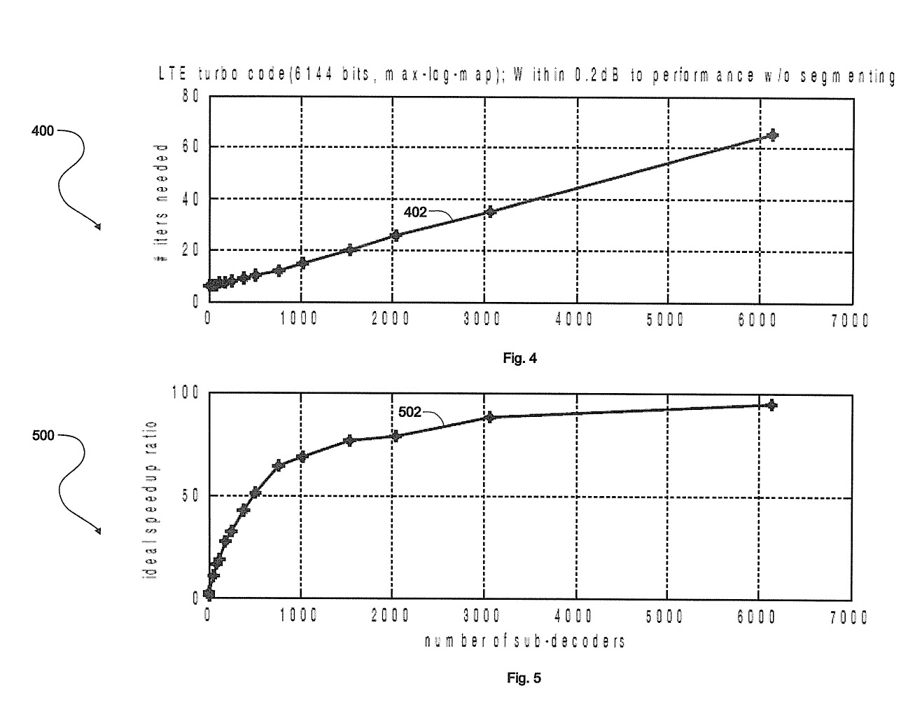

FIG. 4 illustrates a graph 400 showing a curve 402, plotting the number of iterations required (to eliminate or reduce edge effects, against the number of sub-decoders. FIG. 5 illustrates a graph 500 showing a curve 502, plotting an ideal speedup ratio (ISR) against the number of sub-decoders. Define ISR=(Number of Sub-decoders)/(number of iterations needed). (Assume that decoding time of sub-decoder is linearly scaled down by Number of Sub-decoders (larger Number of Sub-decoders providing for fewer processing bits per sub-decoder). Meanwhile, the decoding time of a sub-decoder is linearly scaled up by the number of iterations).

In many prior-art approaches, the number of sub-decoders is less than 128, so as to maintain enough length of bits for each sub-decoder. One or more embodiments of the invention expand the number of sub-decoders to the maximum code length 6144, and the speedup ratio is shown. Alternatively, choosing the number of sub-decoders around the corner point around 512, 768 or 1024 sub-decoders in FIG. 5 is a good tradeoff point for balancing the advantage of an increased speedup ratio against increased complexity associated with an increased number of sub-decoders.

The use of parallel threads can achieve even greater efficiency through more efficient use of memory, such as the use of contiguous or contiguously addressed memory locations. Therefore, one or more embodiments of the invention organize data such as the original block of info0, info 1, parity0, and parity1 so that that massive parallel threads can access a memory region with successive addresses.

Suppose that there are M data elements (s[0], s[1] . . . s[m] . . . to s[(M−1)]) are stored in memory from addresses
[0], [1], . . . [m] . . . , to [M−1])
   to be processed by P sub-decoders. Sub-decoders are noted as:
d_{—}0, d_{—}1 . . . d_p . . . to d_(P−1)),
   where M is an integral multiple of P.

In prior-art approaches, sub-decoder d_p processes from
s[(p*M/P)], s[(p*M/P)+1] . . . s[(p*M/P)+i] . . . , to s[(p*M/P)+(M/P)−1].

This means that at time instance i, all sub-decoders need to obtain s[(0*M/P)+i], s[(1*M/P)+i], . . . , s[((p−1)*M/P)+i] concurrently. Such (M/P) access provides for a low efficiency for a GPGPU memory system, due to a stride memory access pattern. Parallel read from consecutive memory addresses can be implemented in processor hardware much more efficiently.

One or more embodiments of the invention achieve a higher efficiency by arranging M data elements in an address pattern as follows:
s[m]=floor(m/(M/P))+P*(m−(M/P)*floor(m/(M/P))).

Note the new data block after rearrangement as
s_new[0], s_new[1], . . . , s_new[M−1].
   It can be seen that s_new[new_address_of_s[m]]=s[m]. Thus, at time instance i, all sub-decoders should access
s_new[i*P+0], s_new[i*P+1], . . . s_new[i*P+p, . . . i*P+p−1]
   concurrently to obtain the original
s[(0*M/P)+i], s[(1*M/P)+i], . . . , s[((p−1)*M/P)+i]. Rather than using an approach similar to stride (M/P) access of s, embodiments of the invention perform a block of P accesses of s_new, with a resulting increase in memory access efficiency.

Extrinsic and extrinsic_new buffer can be accessed in a similar way. Notice that the contents of extrinsic and extrinsic_new buffer are generated by sub_decoder, and that their data arrangement can be determined by a native sub-decoder write operation. Each time a de-interleaved (first half sub-decoder) or interleaved (second half sub-decoder) write address x in logical extrinsic_new (first half sub-decoder) or extrinsic (second half sub-decoder) the data should be written to address y, where y=d+t; d=floor(x/(M/P)); t=(x-d*(M/P))*P. Thus concurrent P read operations from all sub-decoders targeting blocks of successive addresses would ensure that every sub-decoder receives correct data.

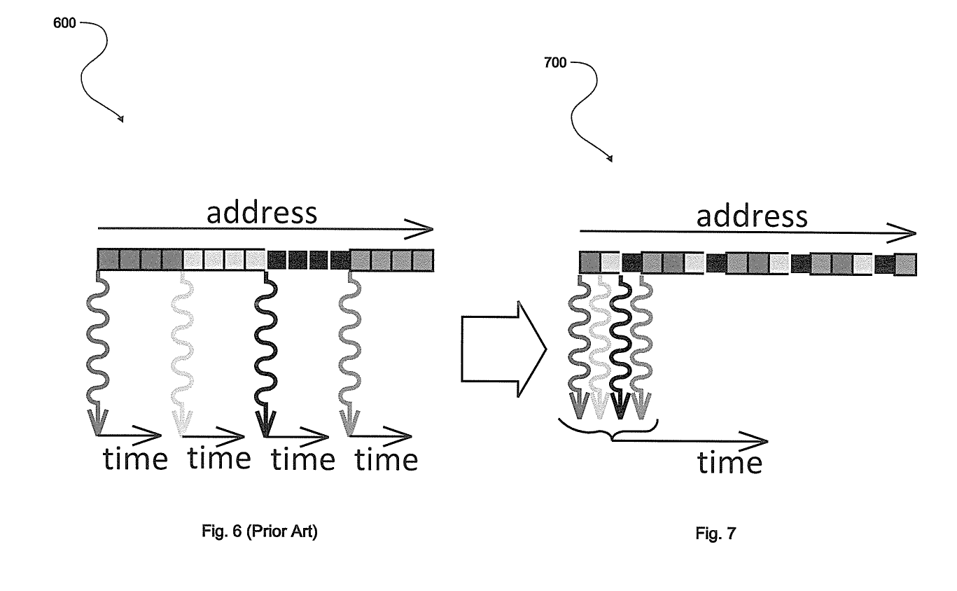

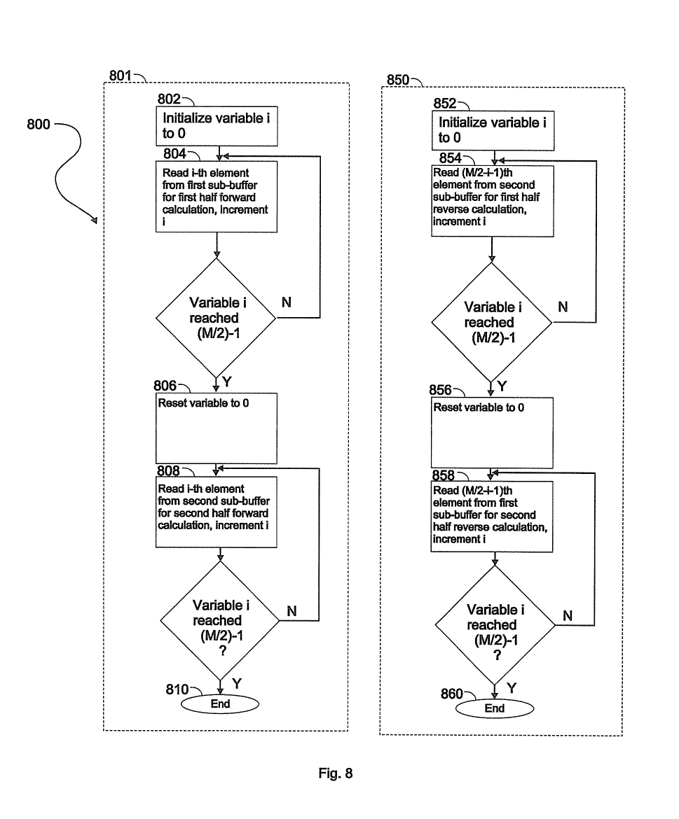

FIG. 6 illustrates a prior-art addressing arrangement 600, and FIG. 7 illustrates an addressing arrangement 700 according to an embodiment of the invention. From a comparison with the addressing arrangements 600 and 700, it can be seen that the arrangement 700 arranges memory addresses as they will be needed by sub-decoders rather than according to the initial relationship of the data elements to one another. The arrangement 702 provides for significant time savings.

Embodiments of the invention also manage buffering in such a way as to allow a compiler to readily identify parallelism of concurrent memory accessing from forward and reverse transversal. In order to achieve this goal, embodiments of the invention may use two pre-defined sub-buffer objects to represent one original buffer, where two sub-buffers are non-overlapped. The first sub-buffer is defined by a parameter pair
{0, sizeof(element type)*M/2};
   the second sub-buffer is defined by
{sizeof(element type)*M/2, sizeof(element type)*M/2},
   where:
first parameter is sub-buffer start address in original buffer,
second parameter is sub-buffer size,
sizeof(element type) is the size of one element of original buffer,
M is the number of elements of the original buffer.

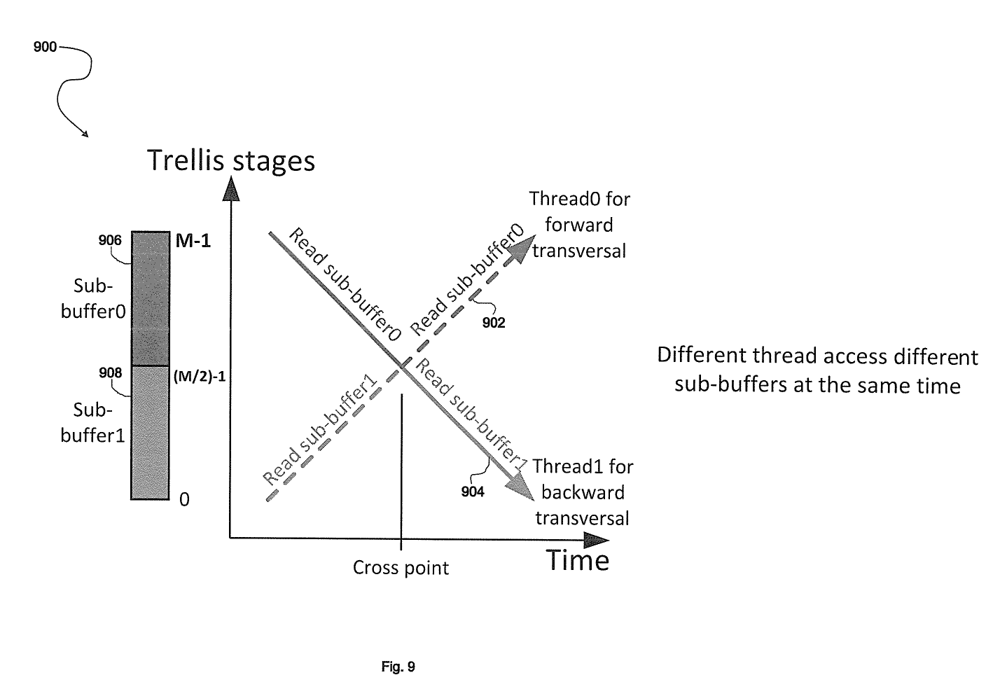

FIG. 8 illustrates a process 800, presenting an approach to forward and reverse transversal accessing of two sub-buffers. The process 800 comprises simultaneous sub-processes 801 and 850. This concurrent access by sub-buffers may be the same in the first half and the second half iteration.

For the first sub-process 801, at step 802, a variable i is initialized to 0. At step 804, the i-th element is read from a first sub-buffer for first half forward calculation, and i is incremented. If the variable i has not reached (M/2)−1, the process returns to step 804. Once the variable i reaches (M/2)−1, the process proceeds to step 806 and the variable i is reset to 0. Next, at step 808, the ith element is read from the second sub-buffer for second half forward calculation, and i is incremented. If the variable i has not reached (M/2)−1, the process returns to step 808. Once the variable i reaches (M/2)−1, the sub-process 801 ends at step 810.

The second sub-process 850 takes place simultaneously with the first sub-process 801. At step 852, the counter i is initialized to 0. At step 854, the (M/2−i−1)th element is read from the second sub-buffer for first half reverse calculation and the variable i is incremented. If the variable i has not reached (M/2)−1, the process returns to step 854. Once the variable i reaches (M/2)−1, the process proceeds to step 856 and the variable i is reset to 0. At step 858, the (M/2−i−1)th element is read from the first sub-buffer for a second half reverse calculation, and the variable i is incremented. If the counter has not reached (M/2)−1 the process returns to step 858; if the variable i has reached (M/2)−1, the sub-process 850 ends at step 860.

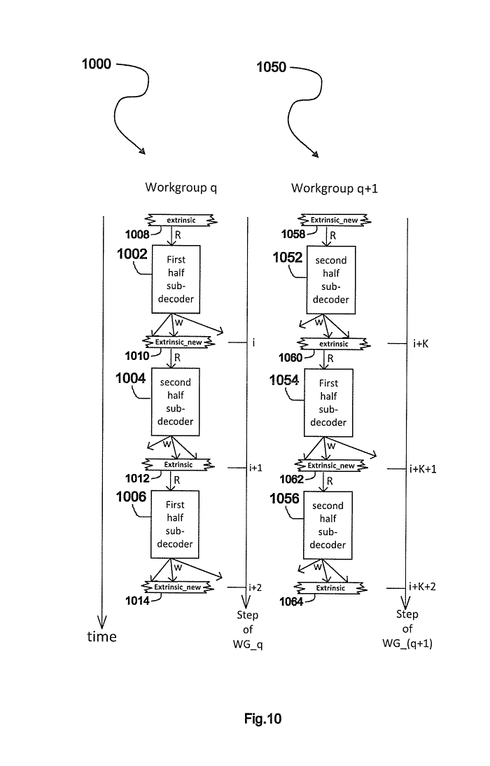

FIG. 9 presents a graphical illustration of a transversal process 900 according to an embodiment of the present invention. The process 900 involves the use of a forward transversal thread 902 and a reverse transversal thread 904 simultaneously. The transversal process 900 employs a first sub-buffer 908 and a second sub-buffer 906.

In the forward transversal thread 902, the first sub-buffer 908 and then the second sub-buffer 906 are read, and at the same time, in the reverse transversal thread 904, the second sub-buffer and then the first sub-buffer are read. The forward thread 902 changes from reading the first sub-buffer to reading the second sub-buffer at the same time that the reverse thread changes from reading the second sub-buffer to reading the first sub-buffer.

As noted above, one or more embodiments of the present invention manage synchronization in terms of groups. To decode one block, sub-decoder threads may be divided into many groups. To take an example, if P threads d_{—}0, d_{—}1 . . . d_p . . . d_(P−1)) are used to decode one block, these may be grouped into Q workgroups: WG_{—}0, WG_{—}1, . . . WG_q . . . , WG_(Q−1). That is, WG_q contains threads from d_(q*(P/Q)), d_(q*(P/Q)+1), . . . , to d_(q*(P/Q)+(P/Q)−1).

Threads in the same workgroup are expected to be synchronized. If threats are synchronized with one another, they progress at the same schedule. That is, no second half sub-decoders in a group of synchronized threads starts unless all first half sub-decoders are finished, and no first half sub-decoders will start unless all second half sub-decoders have finished the previous iteration. Such synchronization ensures that all threads can get latest data from the results of previous half iteration.

Generally, one group of threads can be scheduled to one multi-core processor, and that processor guarantees synchronization of all threads in that group. However, maintaining accurate synchronization between many different processors may prove expensive or difficult, especially when there are too many processors in the system.

Therefore, in one or more embodiments of the invention, ranges are defined within which different workgroups are allowed to be asynchronous. Such an approach allows allocation of sub-decoders into several groups and thus different groups, with different groups being allowed to be run in different processors. The workload of each processor can be reduced because each group need contain only a portion of all threads), and overall decoding latency may be reduced accordingly.

One step may be defined as a half sub-decoder (or thread) (or all half sub-decoders or threads in the same workgroup) finishing operation of reading extrinsic memory (or extrinsic_new memory), calculation and writing extrinsic_new memory (or extrinsic memory). If there are I iterations, there would be 2I steps: 0, 1 . . . i . . . 2I−1. Define step difference as step indexes difference between different workgroups at the same time.

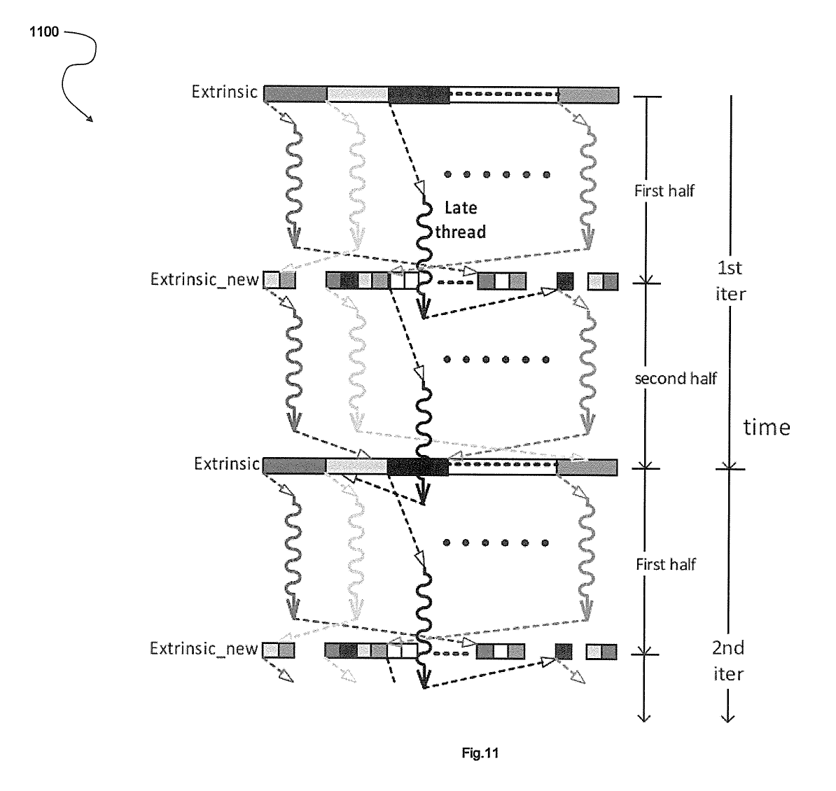

FIG. 10 illustrates first and second workgroups 1000 and 1050, with the first workgroup 1000 comprising a plurality of sub-decoders, here illustrated as first half sub-decoder 1002, second half sub-decoder 1004, first half sub-decoder 1006, and so on, reading and writing extrinsic memory and extrinsic new memory, such as extrinsic memory 1008, extrinsic new memory 1010, extrinsic memory 1012, extrinsic new memory 1014, and so on.

The second workgroup 1005 similarly comprises a plurality of sub-decoders, here illustrated as first half sub-decoder 1052, second half sub-decoder 1054, first half sub-decoder 1056, and so on, reading and writing extrinsic new memory, such as 1058 and 1062, and extrinsic memory 1060. FIG. 10 illustrates a step difference K between the first workgroup 1000 and the second workgroup 1050.

The primary effect of asynchronous threads is that different threads receive “old” extrinsic or extrinsic_new memory data because some threads have not been able to update the memory in time. Equivalently, even in the case of synchronized threads, segmentation to sub-decoders and using stake memory, the stake memory data is also “old” data of a previous iteration, and this stake memory method has been demonstrated to produce negligible BLER performance loss after several iterations. Because of the nature of iterative processing, this latecoming data effect of extrinsic memory can also be eliminated after sufficiently many.

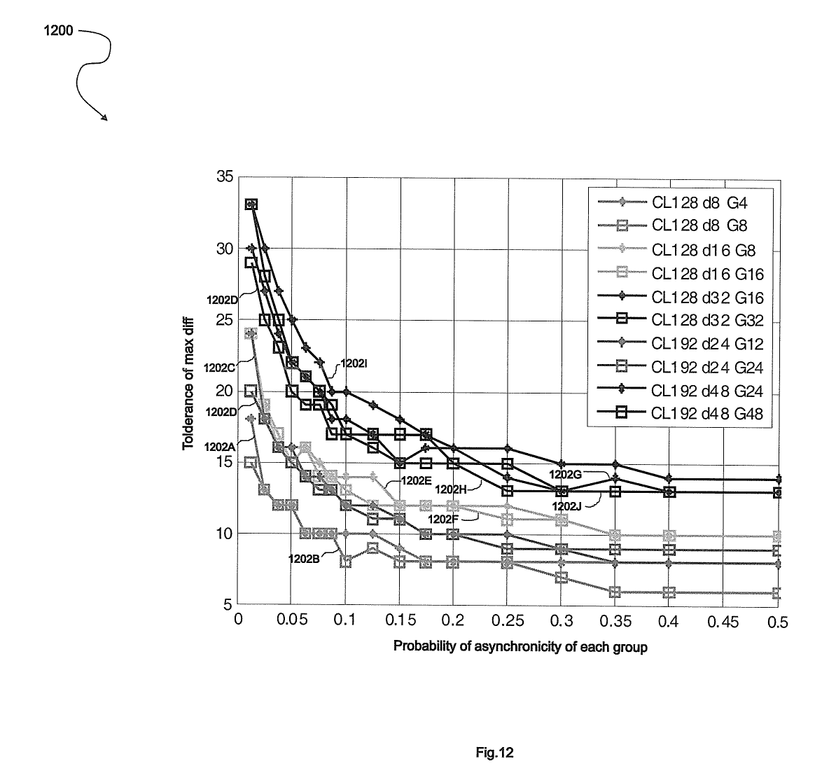

FIG. 11 presents a graphical representation 1100 of asynchronous threads, showing the effects of late threads and old data. The primary effect of asynchronous threads (for example, a late thread, as illustrated in FIG. 11, is that other threads would receive an “old” extrinsic or extrinsic_new memory data because some threads are unable to update the memory in time. As discussed above, even in the case of synchronized threads, case stake memory data is also “old” data from a previous iteration, and this stake memory method has been demonstrated to produce negligible BLER performance loss after several iterations. Because of the nature of iterative processing, this late coming data effect of extrinsic memory also can be eliminated after a sufficient number of iterations.

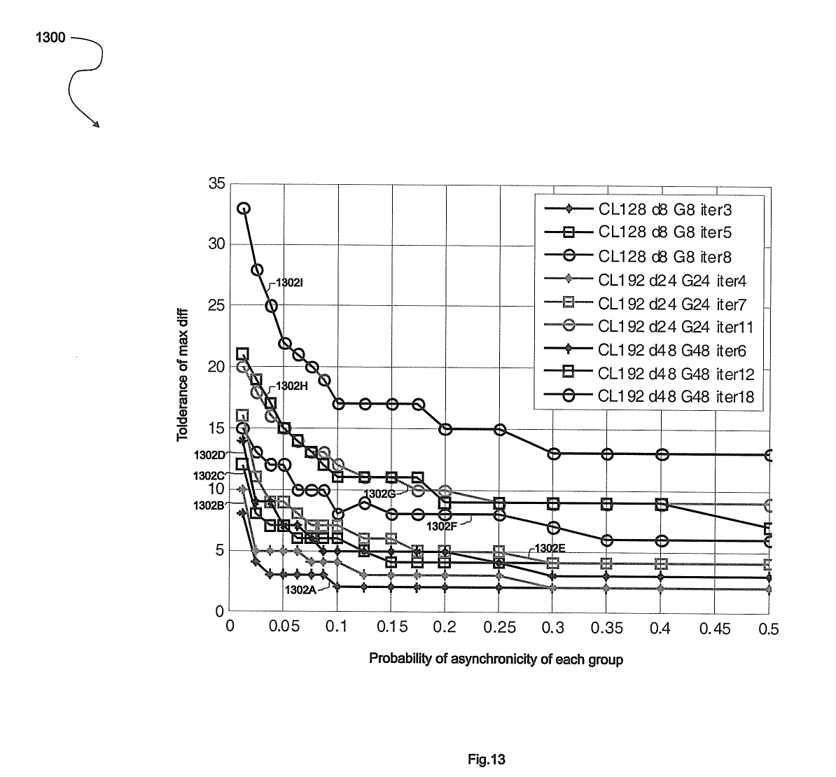

Returning to the discussion of FIG. 10, if each workgroup is asynchronous at probability Pa, and if one workgroup happens to be asynchronous, the step difference is set as max_diff. Once a workgroup step difference is chosen, it will be fixed during all iterations. FIGS. 12 and 13 present graphs 1200 and 1300, respectively, showing tolerance properties for different numbers of sub-decoders, groups, and iterations.

FIG. 12 presents curves 1202A-1202J, with the curves 1202A-1202J plotting tolerance of max_diff against probability of asynchronicity of each group.

In the graph 1200 of FIG. 12, CL128 represents a code length of 128 and CL192 represents a code length of 192; D8, D16, D32, D24, and D48 mean indicate a number of sub-decoders of 8, 16, 32, 24, and 48, respectively, and G4, G8, G16, G32, G12, G24, and G48 represent a number 4, 8, 16, 32, 12, 24, and 48, respectively, of groups. In of the curves 1202A-1202J, the number of iterations is determined by aligning BLER performance to a 1 sub-decoder case. From above figure, it shows that more sub-decoders, more tolerance to asynchronization. More important, at least max_diff=6 can be tolerated in all cases of above figures, where the minimum number of iterations is 8, and the number of sub-decoders is 8.

The graph 1300 shows curves 1302A-1302I, plotting tolerance of max_diff versus probability of asynchronicity. In the graph 1300 of FIG. 13, CL128 represents a code length of 128 and CL192 represents a code length of 192; D8, D16, D32, D24, and D48 mean indicate a number of sub-decoders of 8, 24, and 48, respectively, and iter3, iter5, iter8, iter4, iter7, iter11, iter6, iter12, and iter18 represent a number 3, 5, 8, 4, 7, 11, 6, 12, and 18, respectively, of iterations.

Attention to the graph 1300 of FIG. 13 shows that tolerance to synchronization increases with the number of iterations. Because an increased number of sub-decoders requires a greater number of iterations at the same code length, examination of FIG. 13 also shows why an increased number of sub-decoders is more tolerant of an increased number of step differences.

One or more embodiments of the invention also provide for efficient mechanisms for partitioning a codeblock among sub-decoders performing non-uniform splitting according to different work load of different processors. Suppose that there are Q processors, and normalized workloads are {q[0], q[1], . . . q[i] . . . q[Q−1]}, where 0≦q[0], q[1], . . . q[i] . . . q[Q−1]≦1, and a higher value represents a heavier workload. The sub-block size belonging to processor i is given by:
Codeblock size*(1−q[i])/(Q−q[0]−q[1]− . . . q[i] . . . −q[Q−1])

After the bit size of each processor is decided, those bits can be partitioned uniformly across decoding threads belonging to that processor.

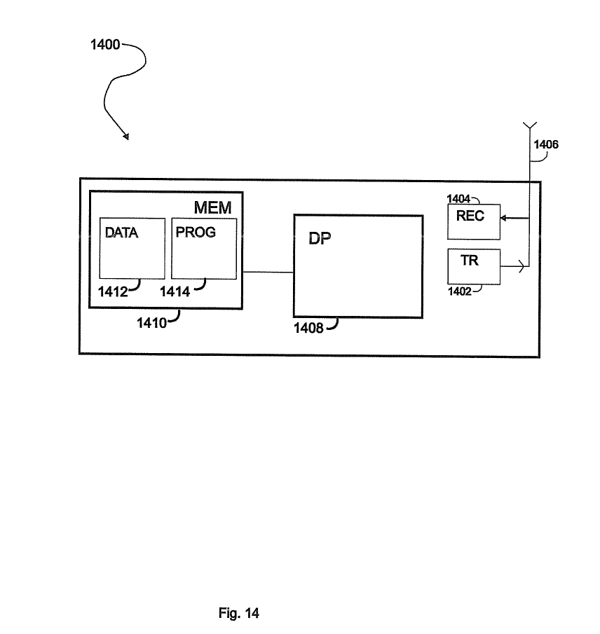

Reference is now made to FIG. 14 for illustrating a simplified block diagram of details of an exemplary device, here implemented as a user equipment (UE) 1400 suitable for communicating using a wireless network, that may be used to carry out an embodiment of the invention.

The UE 1400 also includes a transmitter 1402 and receiver 1404, antenna 1406, one or more DPs 1408, and MEM 1410 that stores data 1412 and one or more programs (PROG) 1414. In at least one embodiment, the DP 1408 may comprise a general purpose graphics processing unit (GPGPU)

At least one of the PROGs 1414 is assumed to include program instructions that, when executed by the associated DP, enable the electronic device to operate in accordance with the exemplary embodiments of this invention as was detailed above in detail.

In general, the exemplary embodiments of this invention may be implemented by computer software executable by the DP 1406, or by hardware, or by a combination of software and/or firmware and hardware. The interactions between the major logical elements should be clear to those skilled in the art for the level of detail needed to gain an understanding of the broader aspects of the invention beyond only the specific examples herein. It should be noted that the invention may be implemented with an application specific integrated circuit ASIC, a field programmable gated array FPGA, a digital signal processor or other suitable processor to carry out the intended function of the invention, including a central processor, a random access memory RAM, read only memory ROM, and communication ports for communicating, for example, channel bits as detailed above.

In general, the various embodiments of the UE 1400 can include, but are not limited to, cellular telephones, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions.

The MEM 1410 may be of any type suitable to the local technical environment and may be implemented using any suitable data storage technology, such as semiconductor based memory devices, magnetic memory devices and systems, optical memory devices and systems, fixed memory and removable memory. The DP 1408 may be of any type suitable to the local technical environment, and may include one or more of general purpose computers, special purpose computers, microprocessors, digital signal processors (DSPs) and processors based on a multi-core processor architecture, as non-limiting examples.

At least one of the memories is assumed to tangibly embody software program instructions that, when executed by the associated processor, enable the electronic device to operate in accordance with the exemplary embodiments of this invention, as detailed by example above. As such, the exemplary embodiments of this invention may be implemented at least in part by computer software executable by the controller/DP of the UE 1400, or by hardware, or by a combination of software and hardware.

Various modifications and adaptations to the foregoing exemplary embodiments of this invention may become apparent to those skilled in the relevant arts in view of the foregoing description. While various exemplary embodiments have been described above it should be appreciated that the practice of the invention is not limited to the exemplary embodiments shown and discussed here.

While various exemplary embodiments have been described above it should be appreciated that the practice of the invention is not limited to the exemplary embodiments shown and discussed here. Various modifications and adaptations to the foregoing exemplary embodiments of this invention may become apparent to those skilled in the relevant arts in view of the foregoing description.

Further, some of the various features of the above non-limiting embodiments may be used to advantage without the corresponding use of other described features.

The foregoing description should therefore be considered as merely illustrative of the principles, teachings and exemplary embodiments of this invention, and not in limitation thereof.

1-33. (canceled)

34. An apparatus comprising:
at least one processor;
memory storing computer program code;
wherein the memory storing the computer program code is configured to, with the at least one processor, cause the apparatus to at least:
define a plurality of sub-decoders for parallel decoding of at least one codeblock of data, wherein the maximum number of sub-decoders defined is limited by a bit length of the at least one codeblock;
divide the at least one codeblock of data into a plurality of sub-blocks, wherein each of the sub-blocks is allocated to one of the sub-decoders;
define a number of iterations to be performed by each sub-decoder, wherein the number of iterations to be performed is based on a number of iterations needed to achieve a targeted block error rate; and
perform simultaneous processing of the sub-blocks by the sub-decoders over the defined number of iterations.

35. The apparatus of claim 34, wherein the sub-decoders perform parallel turbo decoding of the at least one codeblock of data, wherein each of the plurality of sub-decoders comprises a first half and a second half, and wherein the first half sub-decoder and the second half sub-decoder perform simultaneous processing of a portion of a sub-block allocated to the sub-decoder.

36. The apparatus of claim 34, wherein data to be processed by the sub-decoders is arranged in memory such that successive read operations by successive sub-decoders read data in successive memory addresses.

37. The apparatus of claim 34, wherein sub-decoder operations are organized into threads, each thread performing one of a forward transversal operation and a reverse transversal operation, wherein each sub-block is decoded using forward and reverse transversal, wherein each thread accesses memory from one of a first and a second a sub-buffer, wherein at least one forward transversal operation and the at least one reverse transversal operation are performed simultaneously in separate threads, accessing different ones of the first and the second sub-buffers.

38. The apparatus of claim 34, wherein sub-decoder operations are organized into threads and wherein threads are organized into groups, and wherein a number of iterations is defined for each of the sub-decoder operations so as to provide a desired tolerance of asynchronicity between groups.

39. The apparatus of claim 34, wherein the at least one processor comprises multiple processors and wherein the sub-blocks are non-uniformly allocated among processors based on processor workload.

40. The apparatus of claim 34, wherein the at least one processor comprises multiple processors and wherein the sub-blocks are non-uniformly allocated among processors based on processor processing capacity.

41. The apparatus of claim 34, wherein the apparatus is a general purpose graphics processing unit.

42. A method comprising:
defining a plurality of sub-decoders for parallel decoding of at least one codeblock of data, wherein the maximum number of sub-decoders defined is limited by a bit length of the at least one codeblock;
dividing the at least one codeblock of data into a plurality of sub-blocks, wherein each of the sub-blocks is allocated to one of the sub-decoders;
defining a number of iterations to be performed by each sub-decoder, wherein the number of iterations to be performed is based on a number of iterations needed to achieve a targeted block error rate; and
performing simultaneous processing of the sub-blocks by the sub-decoders over the defined number of iterations.

43. The method of claim 42, wherein the sub-decoders perform parallel turbo decoding of the at least one codeblock of data, wherein each of the plurality of sub-decoders comprises a first half sub-decoder and a second half sub-decoder, and wherein the first half sub-decoder and the second half sub-decoder perform simultaneous processing of a portion of a sub-block allocated to the sub-decoder.

44. The method of claim 42, further comprising arranging data to be processed by the sub-decoders in memory such that successive read operations by successive sub-decoders read data in successive memory addresses.

45. The method of claim 42, wherein sub-decoder operations are organized into threads, each thread performing one of a forward transversal operation and a reverse transversal operation, wherein each sub-block is decoded using forward and reverse transversal, wherein each thread accesses memory from one of a first and a second a sub-buffer, wherein at least one forward transversal operation and the at least one reverse transversal operation are performed simultaneously in separate threads, accessing different ones of the first and the second sub-buffers.

46. The method of claim 42, wherein sub-decoder operations are organized into threads and wherein threads are organized into groups, and wherein a number of iterations is defined for each of the sub-decoder operations so as to provide a desired tolerance of asynchronicity between groups.

47. The method of claim 42, wherein the at least one processor comprises multiple processors and wherein sub-blocks are non-uniformly allocated among processors based on processor workload.

48. The method of claim 42, wherein the at least one processor comprises multiple processors and wherein the sub-blocks are non-uniformly allocated among processors based on processor processing capacity.

49. The method of claim 41, wherein the method is carried out by a general purpose graphics processing unit.

50. A method comprising:
dividing at least one block of data to be processed into a plurality of sub-blocks for parallel processing; and
processing the sub-blocks simultaneously in parallel processors over a plurality of iterations, wherein the number of iterations is chosen based on a need to achieve a targeted error rate.

51. The method of claim 50, wherein the iterations are performed asynchronously between sub-blocks.

52. An apparatus comprising:
at least one processor;
memory storing computer program code;
wherein the memory storing the computer program code is configured to, with the at least one processor, cause the apparatus to at least:
divide at least one block of data to be processed into a plurality of sub-blocks for parallel processing; and
process the sub-blocks simultaneously in parallel processors over a plurality of iterations, wherein the number of iterations is chosen based on a need to achieve a targeted error rate.

53. The apparatus of claim 52, wherein the iterations are performed asynchronously between sub-blocks.
